(19) United States
(12) Patent Application Publication
(10) Pub. No.: US 2009/0130819 A1
(43) Pub. Date: May 21, 2009

(54) METHOD FOR MANUFACTURING SEMICONDUCTOR DEVICE

(76) Inventor: Cheon-Man Shim, Yeongdeungpo-gu (KR)

Correspondence Address: SHERR & VAUGHN, PLLC, 620 HERNDON PARKWAY, SUITE 200, HERNDON, VA, 20170, US

(21) Appl. No.: 12/263,524

(22) Filed: Nov. 3, 2008

(30) Foreign Application Priority Data
Nov. 20, 2007 (KR) 10-2007-0118341

(51) Int. Cl. H01L 21/311; H01L 21/76

(52) U.S. Cl. 438/424; 438/700; 257/E21.546

(57) ABSTRACT

A method of manufacturing a semiconductor device includes a device isolation layer. In the method, a hard mask may be formed on a semiconductor substrate, and the semiconductor substrate may be etched using the hard mask as a mask to form a trench. The hard mask may be removed, and a device isolation layer may be formed in the trench. A shallow trench isolation pattern having an excellent layer quality may be formed by reducing an aspect ratio of the trench in the semiconductor device and gap-filling a dielectric. Thus, the number of defects may be decreased.

The present application claims priority under 35 U.S.C. 119 to Korean Patent Application No. 10-2007-0118341 (filed on Nov. 20, 2007), which is hereby incorporated by reference in its entirety.

### BACKGROUND

With the fast market penetration of information appliances such as the computer, remarkable development in semiconductor device technology has occurred in recent years. In terms of function, semiconductor devices are now required to have mass storage capacity and high-speed data processing ability. Responding to such requirements, manufacturing technologies for semiconductor devices are being rapidly developed with a focus on increasing integration, reliability, and response speed.

As such, semiconductor devices have become more miniaturized by methods of manufacturing increasingly integrated semiconductor devices. In a miniaturizing method for semiconductor devices, a technology for miniaturizing both a device isolation layer and a metal interconnection has become an important factor in integrating many devices.

### SUMMARY

Embodiments provide a method of manufacturing a semiconductor device including a device isolation layer having excellent trench filling performance. In embodiments, a method of manufacturing a semiconductor device comprises: forming a hard mask on a semiconductor substrate, etching the semiconductor substrate using the hard mask as an etching mask to form a trench, removing the hard mask, and forming a device isolation layer in the trench.

In embodiments, a shallow trench isolation pattern with an excellent layer quality may be formed by reducing an aspect ratio of a trench in a semiconductor device and gap-filling a dielectric. Thus, the number of defects may be decreased.

### DRAWINGS

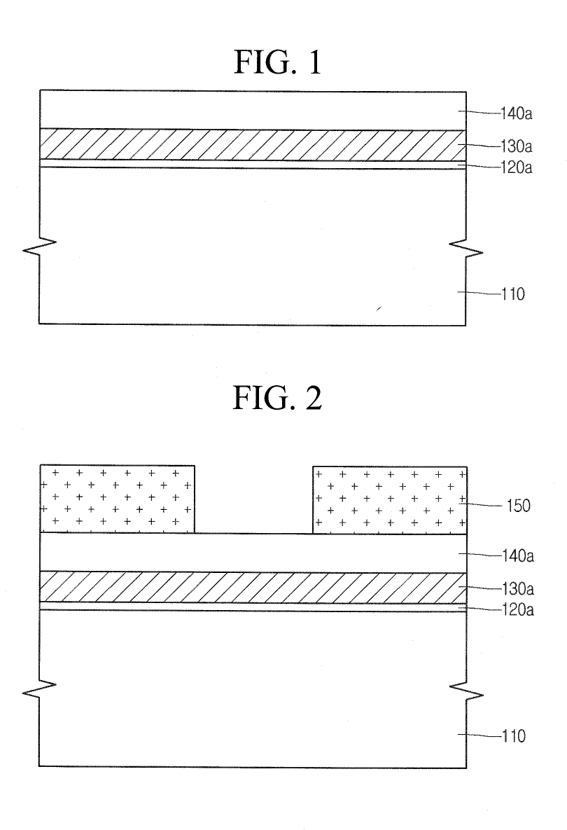

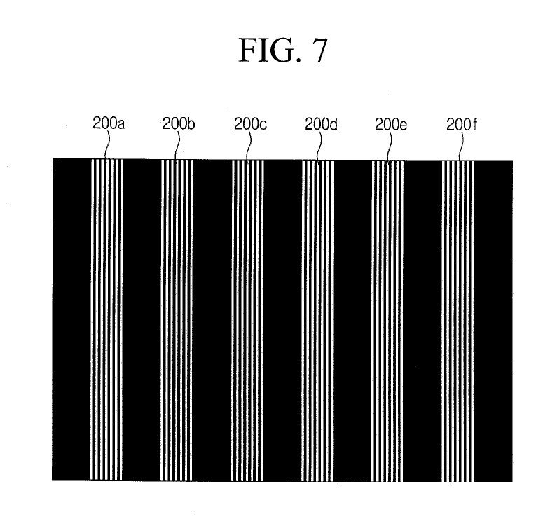

Example FIGS. 1 to 6 are cross-sectional views illustrating a method of manufacturing a semiconductor device according to embodiments.

Example FIG. 7 is a plan view illustrating line/space patterns using a method of manufacturing a semiconductor device according to embodiments.

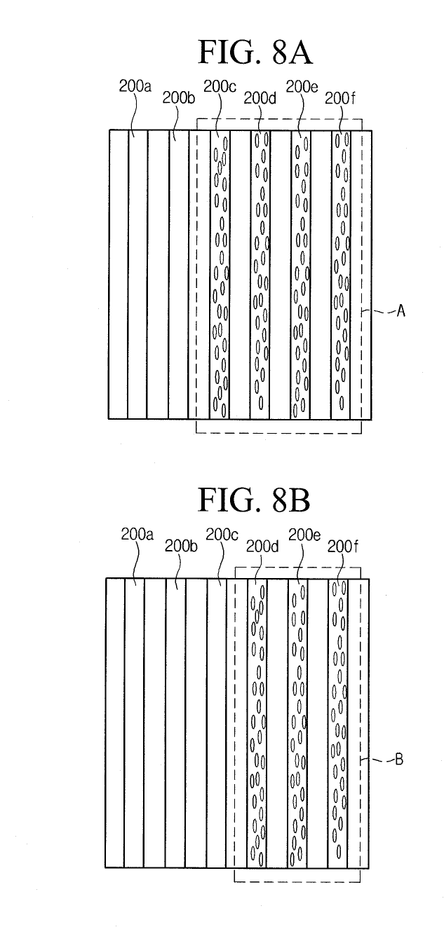

Example FIGS. 8A and 8B are optical microscope images illustrating semiconductor devices formed using the patterns of example FIG. 7.

### DESCRIPTION

Example FIGS. 1 to 6 are cross-sectional views illustrating a method of manufacturing a semiconductor device according to embodiments. Referring to example FIG. 1, a pad oxide layer 120a, a pad nitride layer 130a, and a mask layer 140a are sequentially formed on a semiconductor substrate 110. The pad oxide layer 120a may be formed through a chemical vapor disposition (CVD) process or a thermal oxidation process. The thermal oxidation process, for example, may be used to provide a thickness ranging from about 1 nm to 100 nm. The pad nitride layer 130a may be formed, for example, through a CVD process such as a low pressure CVD (LPCVD) process, to have a thickness ranging from about 10 nm to 1,000 nm. The pad oxide layer 120a may serve as a buffer layer to prevent a nitrogen component of the pad nitride layer 130a from permeating into the semiconductor substrate 110. The mask layer 140a may be formed through a CVD process to have a thickness ranging from about 10 nm to 1,000 nm. The mask layer 140a, used to etch the semiconductor substrate 110 to form a trench, may be formed of a hard mask material. For example, the mask layer 140a may be one of a silicon oxynitride (SiON) layer, a silicon oxide (SiO₂) layer and a tetraethylorthsilicate (TEOS) layer.

Referring to example FIG. 2, a photoresist is applied on the mask layer 140a formed on the semiconductor substrate 110. A region for forming a trench 170, illustrated in FIG. 4, is exposed to light and developed to form a photoresist pattern 150. Prior to the applying of the photoresist, an anti-reflective layer may be formed on the mask layer 140a to prevent diffused reflection when the photoresist is exposed to light.

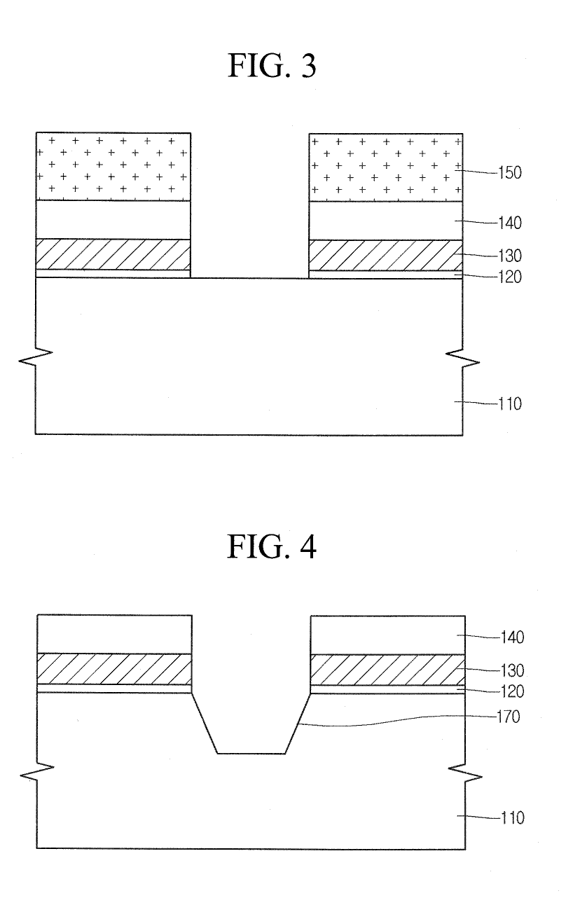

Referring to example FIG. 3, the mask layer 140a, the pad nitride layer 130a, and the pad oxide layer 120a may be etched using the photoresist pattern 150 as an etch mask, to form a hard mask 140, a pad nitride pattern 130, a pad oxide pattern 120.

Referring to example FIG. 4, the photoresist pattern 150 may be removed. Then, the semiconductor substrate 110 may be etched using the hard mask 140 as an etch mask through a reactive ion etching process, so that a trench 170 having a predetermined depth may be formed in the semiconductor substrate 110.

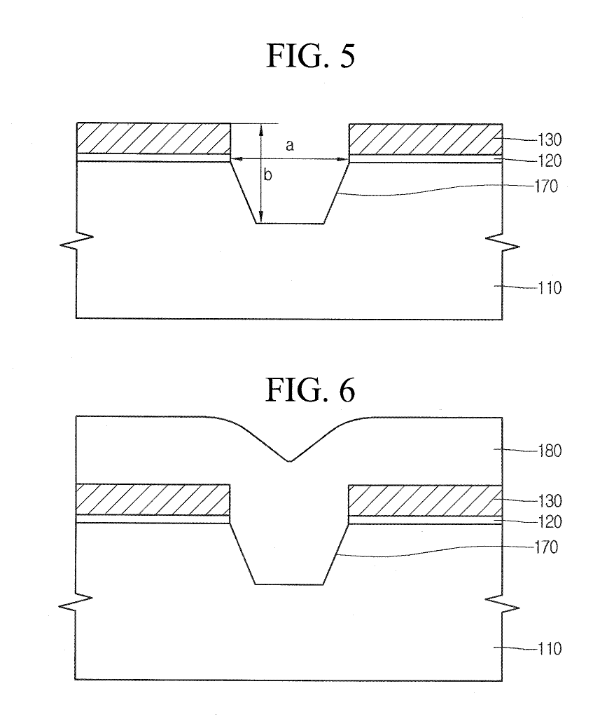

Referring to example FIG. 5, the hard mask 140 on the semiconductor substrate 110 may be removed. The hard mask 140 may be removed through a wet etching process using a hydro fluoric acid (HF) or buffered HF (BHF) solution. The BHF solution may be formed by adding NH₄F to a HF solution. The semiconductor substrate 110 may be washed as part of the wet etching process. Etchants and reaction by-products generated in etching the trench 170 may be removed to improve the subsequent deposition of an oxide layer and product yield. A solution used to etch the hard mask 140 has an etch selectivity with respect to a silicon (Si) and a silicon nitride (SiN), which may substantially prevent damage to the semiconductor substrate 110 and wash-out of a portion of the semiconductor substrate 110 in the pad nitride pattern 130 and the trench 170. The etch selectivity may range from about 1:20 to 1:50. As such, the hard mask 140 may be removed, the pad oxide pattern 120 and the pad nitride pattern 130 are disposed on the semiconductor substrate 10 including the trench 170.

A trench-filling material may be deposited over an entire surface of a structure including the trench 170, to form a device isolation layer 180 filling the trench 170 and covering the pad nitride pattern 130. The device isolation layer 180 may be deposited through an atmospheric pressure chemical vapor deposition (APCVD) method. A trench-filling material for filling the trench 170 may be an O₃-tetraetylorthosilicate (O₃-TEOS). Here, a trench gap-fill performance depends on an aspect ratio of the trench 170, in which the aspect ratio is a value obtained by dividing a vertical length ‘b’ of the trench 170 by a horizontal length ‘a’ thereof. That is, when the aspect ratio is great, the trench 170 is deep, so that the trench gap-fill performance may be poor. When the aspect ratio is small, the trench 170 is shallow and wide, so that the trench gap-fill performance may be good to prevent a defect such as a void. In embodiments, since the hard mask 140 is removed, the aspect ratio is reduced, so that the gap-fill performance of the device isolation layer 180 is improved. Thereafter, the device isolation layer 180 is polished through a chemical mechanical polishing (CMP) process using the pad nitride pattern 130 as an etch stop layer until the pad nitride pattern 130 is exposed to form the device isolation layer 180 in the trench 170.

Example FIG. 7 is a plan view illustrating split line/space patterns to understand a gap-fill performance in a method of manufacturing a semiconductor device according to embodiments. Example FIGS. 8A and 8B are optical microscope images illustrating semiconductor devices formed using the patterns of example FIG. 7.

Referring to example FIG. 8A, a trench is formed in a semiconductor substrate, and then a device isolation layer is formed without removing a hard mask. Referring to example FIG. 8B, a trench is formed in a semiconductor substrate, then a hard mask is removed, and a device isolation layer is formed using a gap-fill process.

Referring to example FIG. 7, the line/space patterns having different sizes from each other were formed as separated first through six patterns 200a, 200b, 200c, 200d, 200e, and 200f. The first pattern 200a had line/space widths of about 0.1 μm/0.14 μm. The second pattern 200b had line/space widths of about 0.11 μm/0.13 μm. The third pattern 200c had line/space widths of about 0.115 μm/0.125 μm. The fourth pattern 200d had line/space widths of about 0.12 μm/0.12 μm. The fifth pattern 200e had line/space widths of about 0.125 μm/0.115 μm. The sixth pattern 200f had line/space widths of about 0.13 μm/0.11 μm.

Referring again to example FIG. 8A, the trench 170 may be formed in the semiconductor substrate 110 under each of the conditions of the first through the sixth patterns 200a, 200b, 200c, 200d, 200e, and 200f. The device isolation layer 180 may be formed, then polished through a CMP process to form the device isolation layer 180 in the trench 170. Then, the pad nitride pattern 130 may be removed. Finally a poly-silicon layer may be formed. In this case, voids may be generated in the trenches 170 formed in a region A under the conditions of the third through the sixth patterns 200c, 200d, 200e, and 200f. The poly-silicon layer may be deposited in these voids, which is illustrated as unevenness in the optical microscope image of FIG. 8A.

Referring again to example FIG. 8B, the trench 170 may be formed on the semiconductor substrate 110 under each of the conditions of the first through the sixth patterns 200a, 200b, 200c, 200d, 200e, and 200f. The device isolation layer 180 may be formed, then polished through a CMP process to form the device isolation layer 180 in the trench 170. The pad nitride pattern 130 is removed. Finally a poly-silicon layer is formed. In this case, voids may be generated in the trenches 170 formed in a region B under the conditions of the fourth through the sixth patterns 200d, 200e, and 200f. The poly-silicon layer is deposited in these voids, which is illustrated as unevenness in the optical microscope image of example FIG. 8A. That is, when the hard mask 140 was removed, a void was not seen until 0.125 μm. Therefore, when the hard mask 140 is removed, the device isolation layer 180 may be formed in the trench 170, thereby improving a shallow trench isolation gap-fill (STI) performance and improving process tolerance.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
forming a hard mask over a semiconductor substrate;
etching the semiconductor substrate using the hard mask as an etching mask to form a trench; and then
removing the hard mask; and then
forming a device isolation layer in the trench.

2. The method of claim 1, comprising forming the hard mask using one of a silicon oxynitride layer and a silicon oxide layer.

3. The method of claim 1, wherein removing the hard mask includes a wet etching process using one of a hydro fluoric acid solution and a buffered hydro fluoric acid solution.

4. The method of claim 1, wherein forming the hard mask comprises:
forming a nitride layer over the semiconductor substrate; and then
forming a mask layer over the nitride layer; and then
forming a photoresist pattern over the mask layer; and then
patterning the mask layer and the nitride layer using the photoresist pattern as an etch mask, to form the hard mask and a nitride pattern.

5. The method of claim 4, wherein the mask layer is formed to have a thickness in a range between approximately 10 nm to 1000 nm.

6. The method of claim 4, further comprising, before forming the nitride layer over the semiconductor substrate, forming an oxide layer over the semiconductor substrate.

7. The method of claim 6, wherein the oxide layer is formed through a thermal oxidation process.

8. The method of claim 6, wherein the oxide layer is formed with a thickness in a range between approximately 1 nm to 100 nm.

9. The method of claim 6, wherein forming the hard mask and the nitride pattern comprises etching the oxide layer using the photoresist pattern as an etch mask to form an oxide pattern over the semiconductor substrate.

10. The method of claim 4, wherein the nitride layer is formed to have a thickness in a range between approximately 10 nm to 1000 nm.

11. The method of claim 1, further comprising forming an anti-reflective layer over a mask layer.

12. The method of claim 1, wherein forming the device isolation layer in the trench comprises:
forming the device isolation layer to cover an entire surface of the semiconductor substrate including the trench; and then
polishing the device isolation layer through a chemical mechanical polishing process using a nitride layer as an etch stop layer until the nitride layer is exposed.

13. The method of claim 12, wherein the device isolation layer is deposited using an atmospheric pressure chemical vapor deposition method.

14. The method of claim 1, wherein etching the semiconductor substrate is performed using a reactive ion etching process.

15. The method of claim 1, wherein removing the hard mask includes a wet etching process using one of a hydro fluoric acid solution and a buffered hydro fluoric acid solution.

16. The method of claim 15, wherein the wet etching process uses an etch selectivity ratio of the semiconductor substrate to the hard mask in a range between approximately 1:20 to 1:50.

17. A method comprising:
forming a nitride layer on a semiconductor substrate; and then
forming a mask layer on the nitride layer; and then
forming a photoresist pattern on the mask layer; and then
simultaneously forming a hard mask and a nitride layer pattern on the semiconductor substrate by patterning the mask layer and the nitride layer using the photoresist pattern as an etch mask; and then
etching the semiconductor substrate using the hard mask as an etching mask to form a trench; and then
removing the hard mask; and then
forming a device isolation layer in the trench.

18. The method of claim 17, further comprising, before forming the nitride layer, forming an oxide layer over the semiconductor substrate through a thermal oxidation process.

19. The method of claim 18, wherein simultaneously forming the hard mask and the nitride layer pattern comprises etching the oxide layer using the photoresist pattern as an etch mask to form an oxide pattern on the semiconductor substrate.

20. The method of claim 17, further comprising forming an anti-reflective layer over a mask layer.
